(19) United States
(12) Patent Application Publication
(10) Pub. No.: US 2013/0083483 A1
(43) Pub. Date: Apr. 4, 2013

(54) HEAT DISSIPATION DEVICE AND ELECTRONIC DEVICE USING SAME

(71) Applicant: CHAO-KE WEI, Tu-Cheng (TW)

(72) Inventor: CHAO-KE WEI, Tu-Cheng (TW)

(73) Assignee: HON HAI PRECISION INDUSTRY CO., LTD., Tu-Cheng (TW)

(21) Appl. No.: 13/598,600

(22) Filed: Aug. 29, 2012

(30) Foreign Application Priority Data
Sep. 30, 2011 (TW) 100135423

(51) Int. Cl. H05K 7/20; H01L 23/467

(52) U.S. Cl. 361/697; 165/121

(57) ABSTRACT

A heat dissipation device is for dissipating heat generated from an electronic device, and includes a fan duct and a heat sink. The fan duct includes a top plate having a receiving hole penetrating therethrough. The heat sink is configured to dissipate heat from a heat-generating electronic component of the electronic device, and includes a base configured to be mounted on the heat-generating electronic component and a number of heat dissipating sheets positioned on the base. The heat dissipating sheets are long enough to extend towards the fan duct and into the receiving hole when the heat dissipation device is installed in the electronic device.

### BACKGROUND

1. Technical Field

The present disclosure relates to heat dissipation technology for electronic apparatuses, and more particularly, to a heat dissipation device and an electronic device using the heat dissipation device.

2. Description of Related Art

Electronic devices such as servers usually employ a heat dissipation device to dissipate heat generated by multiple heat-generating electronic components including a central processing unit in the electronic device. The heat dissipation device includes heat sinks and a fan duct. The heat sinks each include a base mounted on a corresponding heat-generating electronic component, and a plurality of upright fins positioned on the base. The fan duct covers the heat sinks and the corresponding electronic components in the electronic device. The fins of the heat sinks extend towards the fan duct and keep a certain distance from the fan duct. The heat sinks are configured to have increased length of the fins along the extending direction of the fins towards the fan duct, to improve heat dissipation efficiency. However, the fin length of the heat sinks is still limited due to the blockage by the fan duct. Accordingly, it is difficult for each fin to have a large cooling surface area.

What is needed, therefore, is a heat dissipation device and an electronic device using the heat dissipation device which can overcome the described limitations.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the various views, and all the views are schematic.

FIG. 1 is an exploded, isometric view of an electronic device according to a first embodiment of the present disclosure.

FIG. 2 is a slightly enlarged, assembled view of the electronic device of FIG. 1, but omitting a top cover thereof.

FIG. 3 is an assembled view of the electronic device of FIG. 1.

FIG. 4 is an enlarged, cross-sectional view of a portion of the electronic device of FIG. 3, taken along a line IV-IV thereof.

FIG. 5 is similar to FIG. 2, but showing an electronic device according to a second embodiment of the present disclosure.

### DETAILED DESCRIPTION

Reference will now be made to the drawings to describe specific exemplary embodiments of the present disclosure in detail.

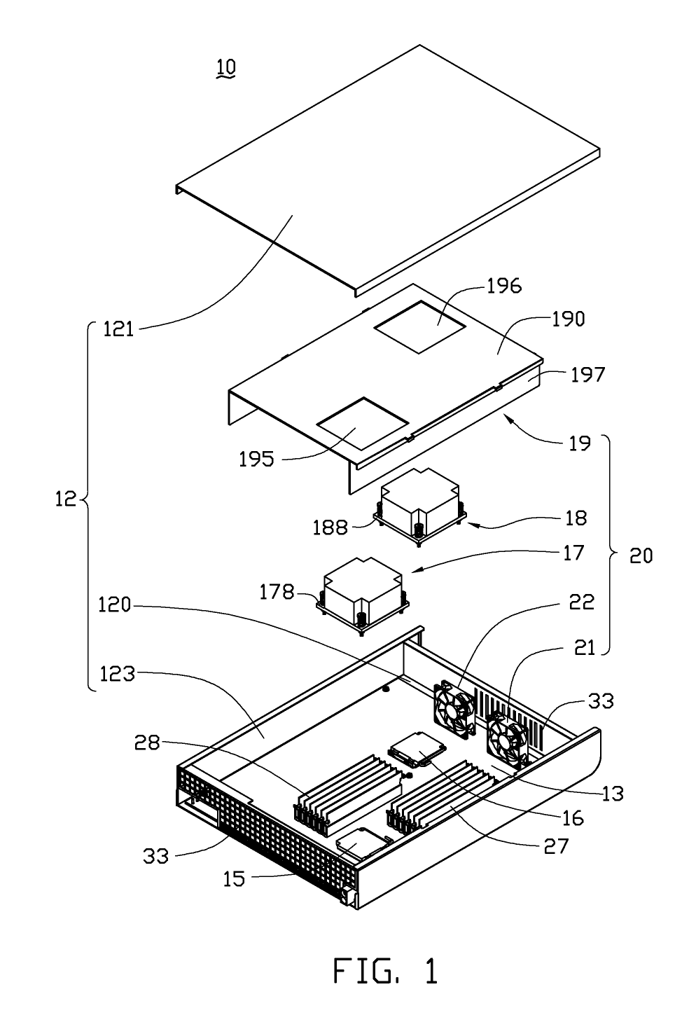

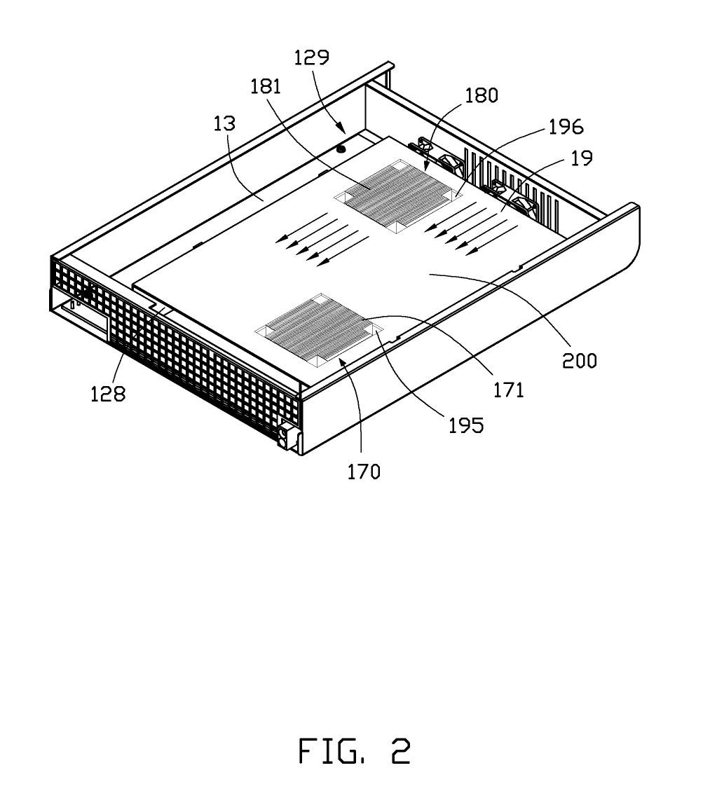

Referring to FIGS. 1-2, an electronic device 10 includes an enclosure 12, a circuit board 13, at least one processor, and a heat dissipation device 20. The circuit board 13, the at least one processor, and the heat dissipation device 20 are received in the enclosure 12. The at least one processor is positioned on the circuit board 13 and is electrically connected to the circuit board 13. The at least one processor may generate large amounts of heat during operation. The heat dissipation device 20 dissipates heat from the at least one processor. In the present embodiment, the at least one processor is two processors, namely a first processor 15 and a second processor 16. The first processor 15 and the second processor 16 may be central processing units (CPUs), for example. In addition, the electronic device 10 further comprises a first memory module 27 and a second memory module 28. The first memory module 27 and the second memory module 28 each include a memory slot (not labeled) electrically connected to the circuit board 13, and a memory (not labeled) inserted into the memory slot. The first processor 15 and the first memory module 27 may be positioned on the circuit board 13 in alignment with each other, for example. The second processor 16 and the second memory module 28 may be positioned on the circuit board 13 in alignment with each other, for example.

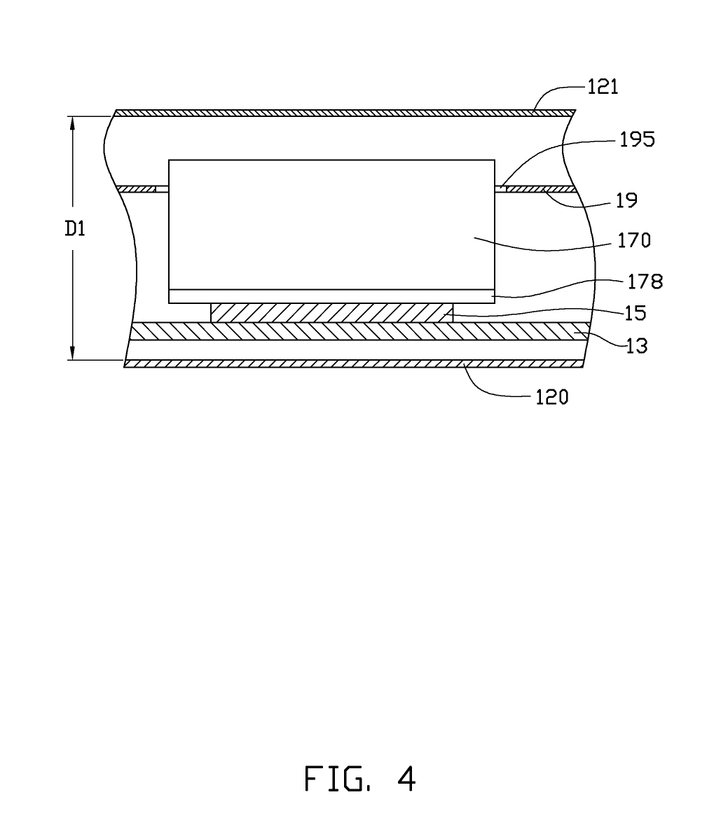

The enclosure 12 defines a first receiving space 129 (shown in FIG. 2), which receives the circuit board 13, the at least one processor, the first memory module 27, the second memory module 28, and the heat dissipation device 20 therein. The enclosure 12 includes a top cover 121, a bottom board 120, and a plurality of sidewalls 123 connecting the top cover 121 with the bottom board 120. The distance between the bottom board 120 and the top cover 121 is D1 (shown in FIG. 4), which is defined as the height of the first receiving space 129. In the illustrated embodiment, the plurality of sidewalls 123 extend from an edge of the bottom board 120, and two opposite front and rear sidewalls 123 each include a plurality of ventilation holes 33.

The heat dissipation device 20 includes at least one heat sink and a fan duct 19. In the present embodiment, the heat dissipation device 20 includes a first heat sink 17 and a second heat sink 18, and the first and second heat sinks 17, 18 are substantially similar to each other. The first heat sink 17 is mounted on the first processor 15. The second heat sink 18 is mounted on the second processor 16. The first heat sink 17 dissipates the heat generated by the first processor 15. The second heat sink 18 dissipates the heat generated by the second processor 16.

In detail, the first heat sink 17 includes a base 178 (shown in FIG. 1) and a plurality of heat dissipating sheets (or plates) 170 (shown in FIG. 2). The base 178 is mounted on the first processor 15. The heat dissipating sheets 170 are perpendicular to the base 178, and are positioned on the base 178 in parallel. Every two adjacent heat dissipating sheets 170 define a channel (not labeled) therebetween, to allow airflow to pass through. The second heat sink 18 includes a base 188 (shown in FIG. 1) and a plurality of heat dissipating sheets 180 (shown in FIG. 2). The base 188 is mounted on the second processor 16. The heat dissipating sheets 180 are perpendicular to the base 188, and are positioned on the base 188 in parallel. Every two adjacent heat dissipating sheets 180 define a channel (not labeled) therebetween, to allow airflow to pass though. The combined height of the first processor 15 and the first heat sink 17 is greater than the height of the first memory module 27. The combined height of the second processor 16 and the second heat sink 18 is greater than the height of the second memory module 28.

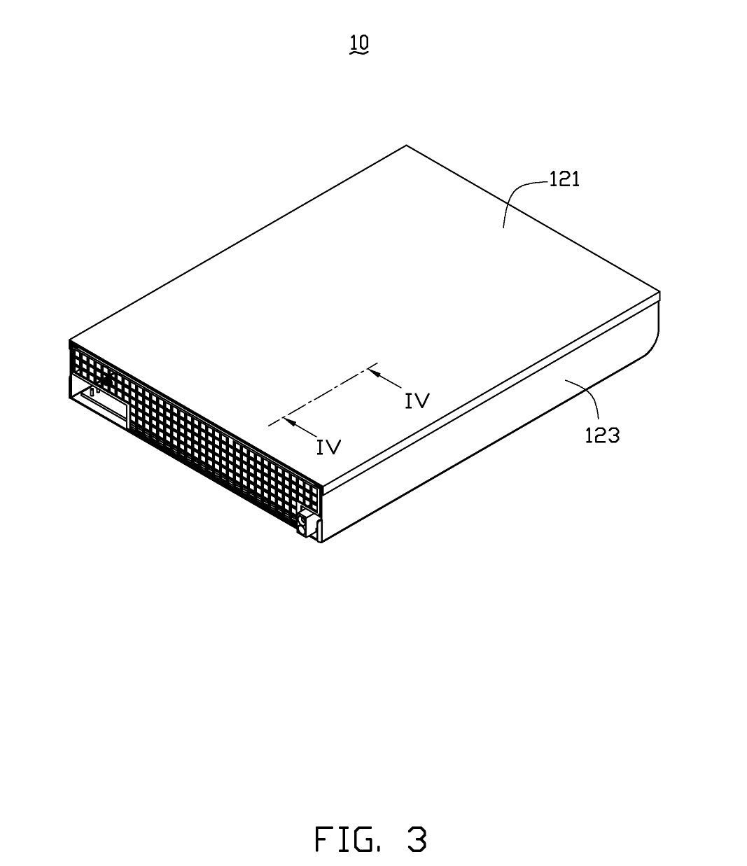

Referring to FIGS. 2-4, the fan duct 19 is positioned between the circuit board 13 and the top cover 121, and is fixed to the circuit board 13. The fan duct 19 and the circuit board 13 cooperatively define a second receiving space 128. The fan duct 19 includes a top plate 190. The top plate 190 defines at least one receiving hole. The number of receiving hole(s) is the same as the number of heat sink(s). That is, the at least one receiving hole corresponds to the at least one processor. In the present embodiment, the at least one receiving hole is two receiving holes, namely a first receiving hole 195 and a second receiving hole 196. The first receiving hole 195 corresponds to the first processor 15 and the first heat sink 17. The heat dissipating sheets 170 extend towards the first receiving hole 195, and have a shape and a size matching with a shape and a size of the first receiving hole 195. The second receiving hole 196 corresponds to the second processor 16 and the second heat sink 18. The heat dissipating sheets 180 extend towards the second receiving hole 196, and have a shape and a size matching with a shape and a size of the second receiving hole 196.

When the fan duct 19 is mounted on the electronic device 10, the heat dissipating sheets 170 extend into the first receiving hole 195, and top surfaces 171 of the heat dissipating sheets 170 facing away from the base 178 are substantially coplanar with an upper surface 200 of the top plate 190 facing away from the base 178. The heat dissipating sheets 180 extend into the second receiving hole 196, and top surfaces 181 of the heat dissipating sheets 180 facing away from the base 188 are substantially coplanar with the upper surface 200 of the top plate 190.

In the present embodiment, the fan duct 19 further includes two opposite sidewalls 197 extending from two opposite edges of the top plate 190 towards the bottom board 120. The sidewalls 197 support the top plate 190, and each of the sidewalls 197 is mounted on one of the bottom board 120 and the circuit board 13. In the present embodiment, both the sidewalls 197 are mounted on the circuit board 13. In addition, a right side of the top plate 190 is fixed to a right one of the sidewalls 123 of the enclosure 12.

In other embodiments, the two opposite sidewalls 197 may be omitted. In such case, a width of the top plate 190 is configured to be substantially the same as a width of the enclosure 12, and the top plate 190 is fixed to both of the sidewalls 197 of the enclosure 12.

The heat dissipation device 20 further includes a first fan 21 and a second fan 22. The first fan 21 and the second fan 22 generate airflow flowing through the first and second heat sinks 17, 18, to enhance heat dissipation into the surrounding air. In detail, the first and second fans 21, 22 are positioned on the front sidewall 123 at the ventilation holes 33 thereof. The first fan 21 faces the channels of the first heat sink 17 defined by the heat dissipating sheets 170. The second fan 22 faces the channels of the second heat sink 18 defined by the heat dissipating sheets 180.

When the heat dissipation device 10 operates, the airflows from the first and second fans 21, 22 pass along the directions of the arrows shown in FIG. 2 under the guidance of the fan duct 19. Because ends of the heat dissipating sheets 170 of the first heat sink 17 facing away from the base 178 are received in the first receiving hole 195, and ends of the heat dissipating sheets 180 of the second heat sink 18 facing away from the base 188 are received in the second receiving hole 196, the first and second heat sinks 17, 18 are higher than comparable heat sinks completely covered by a conventional fan duct. In other words, lengths of the heat dissipating sheets 170 along the extending direction of the heat dissipating sheets 170 towards (and into) the fan duct 19 and lengths of the heat dissipating sheets 180 along the extending direction of the heat dissipating sheets 180 towards (and into) the fan duct 19 are greater than corresponding lengths of conventional heat sinks. Accordingly, cooling surface areas of the heat dissipating sheets 170, 180 are large, thereby enhancing the heat dissipation performance of the electronic device 10.

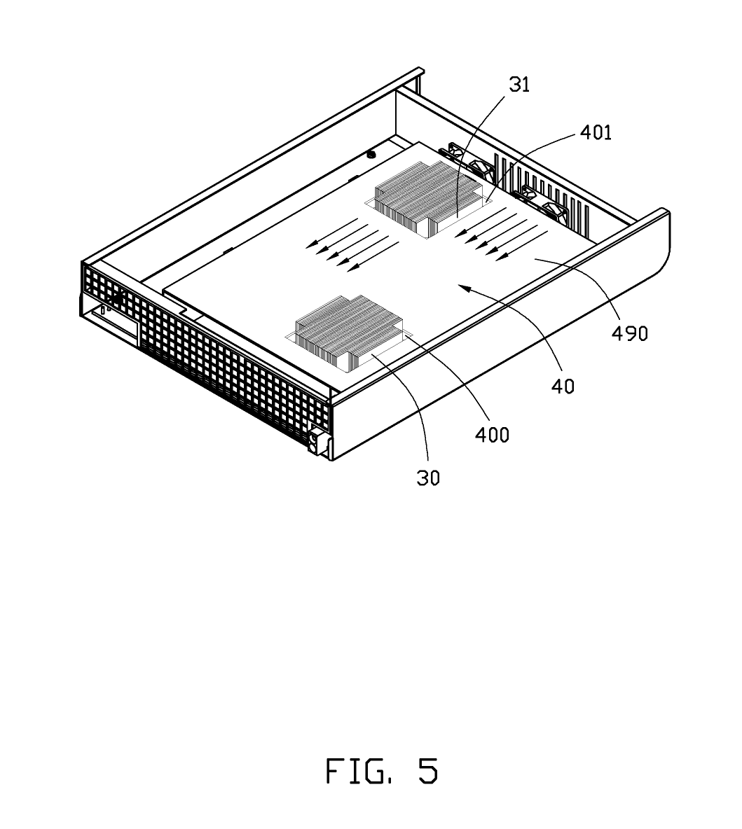

Referring to FIG. 5, in alternative embodiments, a first heat sink 30 may be higher than the first heat sink 17, and a second heat sink 31 may be higher than the second heat sink 18. Accordingly, the first heat sink 30 may extend (protrude) out from a first receiving hole 400 of a top plate 490 of a fan duct 40. The second heat sink 31 may extend (protrude) out from a second receiving hole 401 of the top plate 490 of the fan duct 40.

It is believed that the present embodiments and their advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A heat dissipation device for dissipating heat generated from an electronic device, the heat dissipation device comprising:
a fan duct, comprising a top plate having a receiving hole penetrating therethrough; and
a heat sink, configured to dissipate heat from a heat-generating electronic component of the electronic device, and comprising a base configured to be mounted on the heat-generating electronic component and a plurality of heat dissipating sheets positioned on the base;
wherein the heat dissipating sheets are long enough to extend towards the fan duct and into the receiving hole when the heat dissipation device is installed in the electronic device.

2. The heat dissipation device of claim 1, wherein top surfaces of the heat dissipating sheets are substantially coplanar with an upper surface of the top plate of the fan duct when the heat dissipation device is installed in the electronic device.

3. The heat dissipation device of claim 1, wherein the heat dissipating sheets extend out from the receiving hole above the top plate when the heat dissipation device is installed in the electronic device.

4. The heat dissipation device of claim 1, wherein the fan duct further comprises two opposite sidewalls extending from the top plate, and the sidewalls are configured to be fixed to the electronic device.

5. The heat dissipation device of claim 1, wherein the top plate is configured to be fixed to the electronic device.

6. The heat dissipation device of claim 1, wherein the plurality of heat dissipating sheets of the heat sink has a shape and a size matching with a shape and a size of the receiving hole.

7. The heat dissipation device of claim 1, further comprising a fan for generating airflow flowing through the heat sink under the guidance of the fan duct.

8. An electronic device, comprising:
a heat-generating electronic component; and
a heat dissipation device, comprising:
a fan duct, comprising a top plate having a receiving hole penetrating therethrough; and
a heat sink, configured to dissipate heat from the heat-generating electronic component of the electronic device, and comprising a base mounted on the heat-generating electronic component and a plurality of heat dissipating sheets positioned on the base;
wherein the heat dissipating sheets extend towards the fan duct and into the receiving hole.

9. The electronic device of claim 8, wherein top surfaces of the heat dissipating sheets are substantially coplanar with an upper surface of the top plate of the fan duct.

10. The electronic device of claim 8, wherein the heat dissipating sheets extend out from the receiving hole above the top plate.

11. The electronic device of claim 8, wherein the plurality of heat dissipating sheets of the heat sink has a shape and a size matching with a shape and a size of the receiving hole.

12. The electronic device of claim 8, further comprising a circuit board, wherein the heat-generating electronic component is positioned on the circuit board and is electrically connected with the circuit board.

13. The electronic device of claim 12, wherein the circuit board and the fan duct cooperatively define a first receiving space receiving the heat-generating electronic component and the heat sink.

14. The electronic device of claim 13, further comprising an enclosure comprising a bottom board and a plurality of sidewalls, wherein the bottom board and the plurality of sidewalls cooperatively define a second receiving space receiving the circuit board, the heat-generating electronic component, and the heat dissipation device.

15. The electronic device of claim 14, wherein the circuit board is positioned on the bottom board.

16. The electronic device of claim 15, wherein the fan duct further comprises two opposite sidewalls extending from the top plate, and each of the sidewalls of the fan duct is fixed to one of the circuit board and the bottom board.

17. The electronic device of claim 14, wherein the top plate is fixed to two opposite of the sidewalls of the enclosure.

18. The electronic device of claim 14, wherein the heat dissipation device further comprises a fan positioned on one of the sidewalls of the enclosure for generating airflow through the heat sink under guidance of the fan duct.

19. The electronic device of claim 18, wherein one of the sidewalls of the enclosure opposite to the sidewall on which the fan is positioned comprises a plurality of ventilation holes for allowing the airflow to pass out from the electronic device.

20. An electronic device, comprising:
a circuit board;
a heat-generating electronic component positioned on the circuit board; and
a heat dissipation device, comprising:
a fan duct above the circuit board, the fan duct comprising a top plate having a receiving hole penetrating therethrough; and
a heat sink, configured to dissipate heat from the heat-generating electronic component of the electronic device, and comprising a base mounted on the heat-generating electronic component and a plurality of heat dissipating sheets positioned on the base;
wherein the heat dissipating sheets extend towards the fan duct and into the receiving hole.
